(19) United States
(12) Patent Application Publication
(10) Pub. No.: US 2026/0080946 A1
(43) Pub. Date: Mar. 19, 2026

(54) MEMORY SYSTEM AND CONTROL METHOD

(71) Applicant: Kioxia Corporation, Tokyo (JP)

(72) Inventors: Katsuyuki SHIMADA, Ota Tokyo (JP); Kosuke SAKAI, Hiratsuka Kanagawa (JP)

(21) Appl. No.: 19/068,181

(22) Filed: Mar. 3, 2025

(30) Foreign Application Priority Data
Sep. 18, 2024 (JP) 2024-160552

(51) Int. Cl. G11C 16/26; G06N 20/00

(52) U.S. Cl. CPC G11C 16/26; G06N 20/00

(57) ABSTRACT

A memory system includes a plurality of memory cells and a controller. The controller is configured to acquire a data set corresponding to a distribution of threshold voltages of the plurality of memory cells by reading the plurality of memory cells using a reference read voltage; select one from a plurality of acquisition operations of acquiring an actual read voltage for reading data stored in the plurality of memory cells based on the data set, wherein the plurality of acquisition operations include a first acquisition operation of acquiring the actual read voltage from the data set using a first trained machine learning model and a second acquisition operation different from the first acquisition operation; and acquire the actual read voltage using the selected acquisition operation and read the plurality of memory cells using the acquired actual read voltage.

### CROSS-REFERENCE TO RELATED APPLICATION

This application is based upon and claims the benefit of priority from Japanese Patent Application No. 2024-160552, filed Sep. 18, 2024, the entire contents of which are incorporated herein by reference.

### FIELD

Embodiments described herein relate generally to a memory system and a control method.

### BACKGROUND

Memory systems including semiconductor memories that include memory cell transistors have spread. In such memory systems, predetermined voltages (referred to as read levels) are applied to memory cell transistors in sensing operations, and the memory cell transistors are determined to be in an ON or OFF state under the application of the read levels. Based on determination results, data stored in the memory cell transistors is determined.

### DESCRIPTION OF THE DRAWINGS

FIG. 1 is a diagram illustrating a configuration example of a memory system according to a first embodiment;

FIG. 2 is a diagram illustrating a configuration example of a memory chip;

FIG. 3 is a diagram illustrating a circuit configuration of a block;

FIG. 4 is a diagram illustrating an example of data coding;

FIG. 5 is a diagram m illustrating an example of a distribution of threshold voltages of a memory cell;

FIG. 6 is a diagram illustrating a distribution of threshold voltages of memory cells belonging to either an “A” state or a “B” state;

FIG. 7 is a diagram illustrating an example of a configuration of a first estimator;

FIG. 8 is a diagram illustrating an example of an appearance frequency of a difference bit count group included in each piece of training data;

FIG. 9 is a diagram illustrating an example of a configuration of a second estimator;

FIG. 10 is a diagram illustrating an example of a second acquisition operation;

FIG. 11 is a flowchart illustrating an example of an operation of the memory system;

FIG. 12 is a diagram illustrating a method of generating a histogram input to an estimation matrix according to a first further embodiment of the first embodiment;

FIG. 13 is a diagram illustrating calculation for estimating optimum read level using the estimation matrix;

FIG. 14 is a diagram illustrating a node value of a first estimator according to a second embodiment;

FIG. 15 is a diagram illustrating information to be stored;

FIG. 16 is a flowchart illustrating an example of an operation of a memory system;

FIG. 17 is a diagram illustrating information stored in a RAM according to a third embodiment; and

FIG. 18 is a flowchart illustrating an example of an operation of the memory system.

### DETAILED DESCRIPTION

Embodiments provide a memory system with high performance and a control method therefor.

In general, according to one embodiment, a memory system includes a plurality of memory cells and a controller. The controller is configured to acquire a data set corresponding to a distribution of threshold voltages of the plurality of memory cells by reading the plurality of memory cells using a reference read voltage; select one from a plurality of acquisition operations of acquiring an actual read voltage for reading data stored in the plurality of memory cells based on the data set, wherein the plurality of acquisition operations include a first acquisition operation of acquiring the actual read voltage from the data set using a first trained machine learning model and a second acquisition operation different from the first acquisition operation; and acquire the actual read voltage using the selected acquisition operation and read the plurality of memory cells using the acquired actual read voltage.

A memory system and a control method according to embodiments will be described with reference to the following appended drawings. Embodiments are not limited to these embodiments.

### First Embodiment

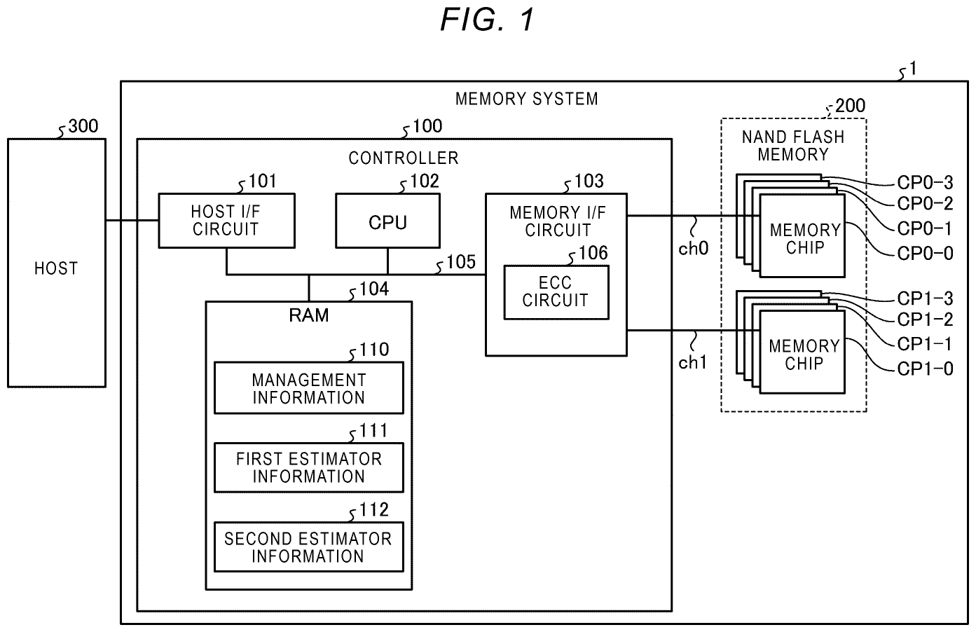

FIG. 1 is a diagram illustrating a configuration example of a memory system according to a first embodiment. As illustrated in FIG. 1, a memory system 1 can be connected to a host 300. The host 300 corresponds to, for example, a server, a personal computer, a mobile information processing device, or the like. The memory system 1 functions as an external storage device of the host 300. The host 300 can issue a command to the memory system 1. Commands to the memory system 1 include a read command and a write command.

The memory system 1 includes a controller 100 and a NAND flash memory 200. The NAND flash memory 200 includes one or more memory chips CP. One or more channels are connected to the controller 100. The controller 100 and the one or more memory chips CP are connected to each other via the one or more channels.

Here, the memory system 1 includes memory chips CP0-0, CP0-1, CP0-2, CP0-3, CP1-0, CP1-1, CP1-2, and CP1-3 as one or more memory chips CP and includes channels ch0 and ch1 as one or more channels. The memory chips CP0-0, CP0-1, CP0-2, and CP0-3 are connected to the controller 100 via the channel ch0. The memory chips CP1-0, CP1-1, CP1-2, and CP1-3 are connected to the controller 100 via the channel ch1. The number of memory chips CP in the memory system 1 is not limited to 8. The number of channels connected to the controller 100 is not limited to 2. A connection relationship between the controller 100 and the one or more memory chips CP is not limited to the foregoing relationship.

Each memory chip CP includes a plurality of memory cell transistors and can store data in a nonvolatile manner. The controller 100 includes a host interface (I/F) circuit 101, a central processing unit (CPU) 102, a memory interface (I/F) circuit 103, a random access memory (RAM) 104, and a bus 105. The host interface circuit 101, the CPU 102, the memory interface circuit 103, and the RAM 104 are electrically connected to the bus 105. The memory interface circuit 103 includes an error-correcting code (ECC) circuit 106.

The controller 100 can be configured as, for example, a system-on-a-chip (SoC). The controller 100 may be configured with a plurality of chips. The controller 100 may include a field-programmable gate array (FPGA) or an application specific integrated circuit (ASIC) instead of the CPU 102. That is, the controller 100 can be configured by software, hardware, or a combination thereof. The RAM 104 may be disposed outside of the controller 100.

The host interface circuit 101 is connected to the host 300 via a bus conforming with a predetermined standard and is in charge of communication between the controller 100 and the host 300.

The memory interface circuit 103 is connected to the eight memory chips CP via two channels and is in charge of communication between the controller 100 and each memory chip CP.

The CPU 102 controls an operation of the controller 100.

The RAM 104 is used as a work area of the CPU 102. The RAM 104 is used as a buffer area where data to be transmitted to the memory chips CP and data received from the memory chips CP are temporarily stored. The RAM 104 can be configured with, for example, a dynamic random access memory (DRAM), a static random access memory (SRAM), or a combination thereof. A type of memory configuring the RAM 104 is not limited thereto.

While the memory system 1 operates, management information 110, first estimator information 111, and second estimator information 112 are stored in the RAM 104. The management information 110, the first estimator information 111, and the second estimator information 112 will be described below.

The ECC circuit 106 detects an error using an error-correcting code and corrects the detected error. The detection of the error and the correction of the detected error are referred simply to as error correction.

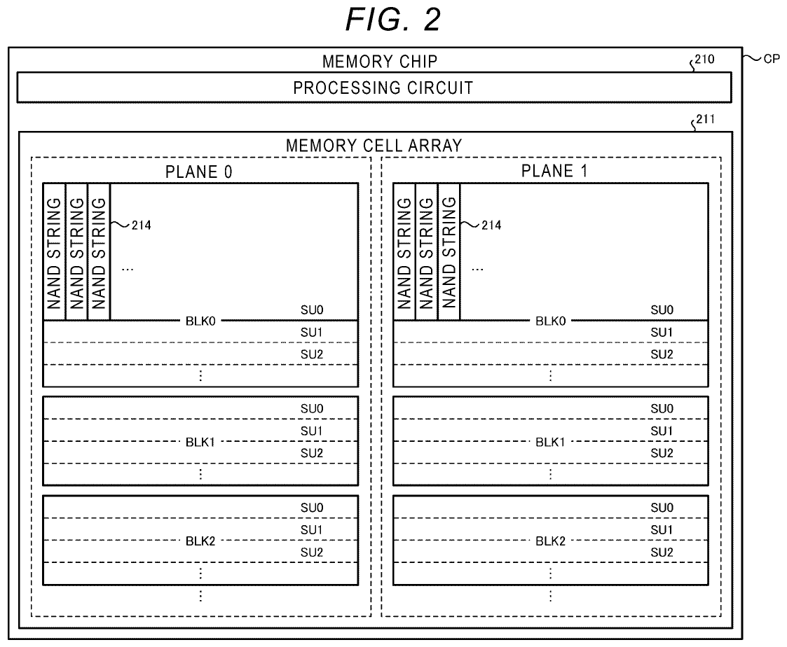

FIG. 2 is a diagram illustrating a configuration example of a memory chip CP according to the first embodiment. The memory chips CP0-0, CP0-1, CP0-2, CP0-3, CP1-0, CP1-1, CP1-2, and CP1-3 can have a common configuration.

In the example illustrated in FIG. 2, the memory chip CP includes a processing circuit 210 and a memory cell array 211.

The memory cell array 211 is divided into, for example, a plurality of planes (plane 0 and plane 1). Each plane is a sub-array that can be accessed in parallel. Each plane includes a plurality of blocks BLK (BLK0, BLK1, . . . ) that are a set including a plurality of nonvolatile memory cell transistors. Each of the blocks BLK includes a plurality of string units SU (SU0, SU1, . . . ) that are a set including memory cell transistors associated with word lines and bit lines. Each of the string units SU includes a plurality of NAND strings 214 in which memory cell transistors are connected in series. Any number of NAND strings 214 in the string unit SU can be used. The number of planes in the memory cell array 211 is not limited to 2. The memory cell array 211 may not necessarily be divided.

The processing circuit 210 includes, for example, a row decoder, a column decoder, a sense amplifier, a latch circuit, and a voltage generation circuit. The processing circuit 210 executes a program operation, a sensing operation, an erase operation on the memory cell array 211 of each plane in response to a command from the controller 100.

The program operation is an operation of writing data on the memory cell array 211. The sensing operation is an operation of reading data from the memory cell array 211.

A series of operations in which the controller 100 writes data on the memory chip CP is referred to as a write operation. The write operation includes a data-in operation in which the controller 100 transmits data to the memory chip CP and a program operation in which the processing circuit 210 writes data received through the data-in operation on the memory cell array 211.

A series of operations in which the controller 100 reads data from the memory chip CP is referred to as a read operation. The read operation includes a sensing operation in which the processing circuit 210 reads data from the memory cell array 211 and a data-out operation in which the controller 100 acquires data read through the sensing operation from the memory chip CP.

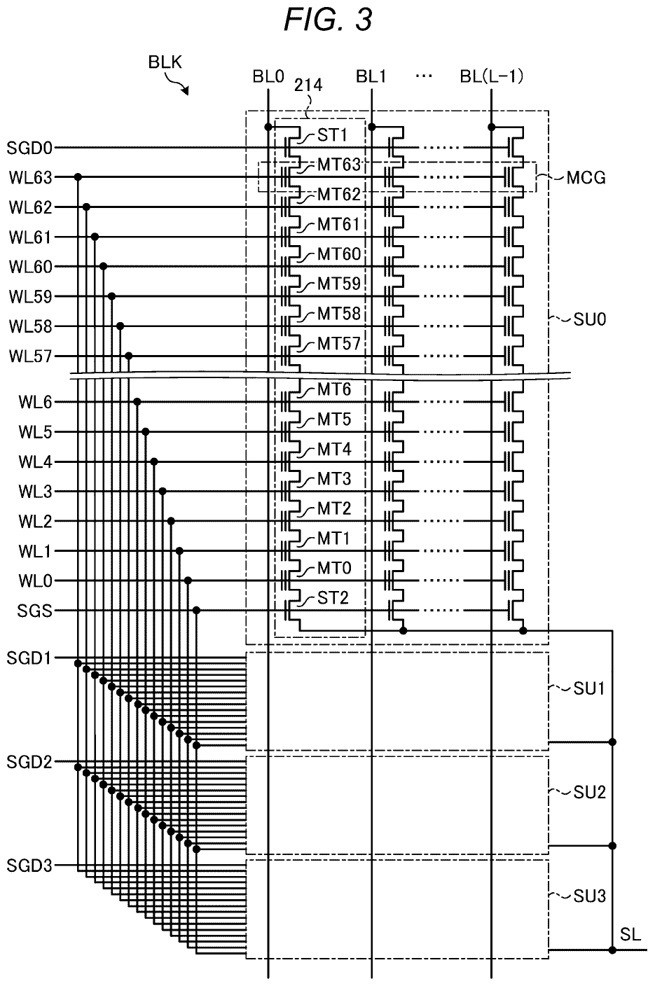

FIG. 3 is a diagram illustrating a circuit configuration of a block BLK according to the first embodiment. Each block BLK has the same configuration. The block BLK includes, for example, four string units SU0 to SU3. Each string unit SU includes a plurality of NAND strings 214.

Each of the NAND strings 214 includes, for example, sixty four memory cell transistors MT (MT0 to MT63) and select transistors ST1 and ST2. The memory cell transistor MT includes a control gate and a charge storage layer and stores data in a nonvolatile manner. The sixty four memory cell transistors MT (MT0 to MT63) are connected in series between a source of the select transistor ST1 and a drain of the select transistor ST2. The memory cell transistor MT may be a MONOS type transistor in which an insulating layer is used for a charge storage layer or may be an FG type in which a conductive film is used for a charge storage layer. Further, the number of memory cell transistors MT in the NAND string 214 is not limited to 64.

Gates of the select transistors ST1 in the string units SU0 to SU3 are connected to select gate lines SGD0 to SGD3, respectively. On the other hand, gates of the select transistors ST2 in the string units SU0 to SU3 are commonly connected to, for example, a select gate line SGS. The gates of the select transistors ST2 in the string units SU0 to SU3 may be connected to different select gate lines for each string unit SU. Control gates of the memory cell transistors MT0 to MT63 in the same block BLK are each commonly connected to word lines WL0 to WL63.

The drain of the select transistor ST1 of each NAND string 214 in the string unit SU is connected to a different bit line BL (BL0 to BL(L−1) where L is a natural number of 2 or more). The bit lines BL commonly connect one NAND string 214 in each string unit SU between the plurality of blocks BLK. Further, the source of each select transistor ST2 is commonly connected to the source line SL.

That is, the string unit SU is a set including the NAND strings 214 connected to the different bit lines BL and the same select gate line SGD. The block BLK is a set including a plurality of string units SU that commonly use a word line WL. The memory cell array 211 is a set including a plurality of blocks BLK that commonly use a bit line BL.

The program operation and the sensing operation on one plane by the processing circuit 210 are collectively executed on the memory cell transistors MT connected to one word line WL in one string unit SU. Hereinafter, a group of the memory cell transistors MT collectively selected during the program operation and the sensing operation on one plane is referred to as a “memory cell group MCG”. A storage area of collection of 1-bit data written on or read from one memory cell group MCG is referred to as a “page”.

The processing circuit 210 can execute an erase operation on one plane in units of blocks BLK.

Hereinafter, the memory cell transistor MT is simply referred to as a memory cell.

In each memory cell, data of n (where n≥1) bits can be written. When n-bit data is written on each memory cell, a storage capacity per memory cell group MCG is equal to a size corresponding to n pages. A mode in which n is 1 is referred to as a single level cell (SLC) mode. A mode in which n is 2 is referred to as a multi level cell (MLC) mode. A mode in which n is 3 is referred to as a triple level cell (TLC) mode. A mode in which n is 4 is referred to as a quad level cell (QLC) mode.

A threshold voltage of each memory cell is controlled to be within a given range by the processing circuit 210. A controllable range of the threshold voltage is divided into intervals of an nth power of 2 and a different n-bit value is assigned to each interval.

In the embodiment, a mode in which n is 2 or more is adopted. Hereinafter, an example in which a memory cell is used in a TLC mode will be described as an example of the mode in which n is 2 or more. An embodiment is not limited to a system in which a memory cell is used in the TLC mode and can be applied to a system in which a memory cell is used in any mode in which n is 2 or more.

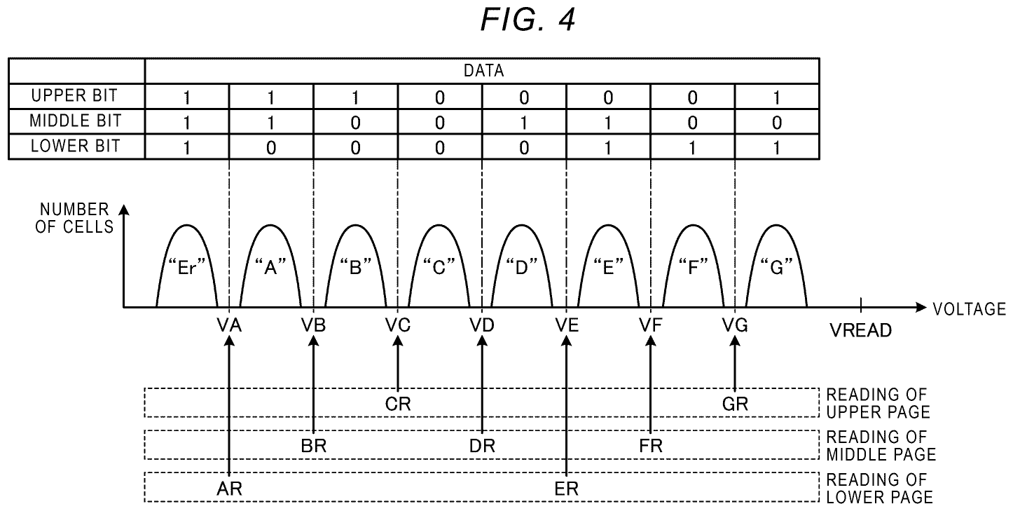

FIG. 4 is a diagram illustrating an example of data coding according to the first embodiment.

As described above, according to the TLC mode, 3-bit data per memory cell is stored. Bits configured in 3-bit data stored in a memory cell are referred to as an upper bit, a middle bit, and a lower bit in this order. Of the three pages included in the memory cell group MCG, a page storing a group of upper bits is referred to as an upper page, a page storing a group of middle bits is referred to as a middle page, and a page storing a group of lower bits is referred to as a lower page.

According to the TLC mode, an allowable range of the threshold voltage is divided into eight intervals. The eight intervals are referred to as an “Er” state, an “A” state, a “B” state, a “C” state, a “D” state, an “E” state, an “F” state, and a “G” state in order from a low threshold. The threshold voltage of each memory cell is controlled by the processing circuit 210 to belong to one of the “Er” state, the “A” state, the “B” state, the “C” state, the “D” state, the “E” state, the “F” state, and the “G” state. As a result, a distribution of threshold voltages in which the number of memory cells is plotted for the threshold voltage ideally has eight lobe shapes that belong to different states and do not overlap each other as illustrated in the middle side of FIG. 4. Hereafter, a distribution for each state is simply referred to as a “lobe”.

The eight states correspond to 3-bit data. A table in the upper side of FIG. 4 shows an example of a correspondence relationship between the states and the 3-bit data, that is, data coding. In this example, the “Er” state corresponds to “111, the “A” state corresponds to “110”, the “B” state corresponds to “100”, the “C” state corresponds to “000”, the “D” state corresponds to “010”, the “E” state corresponds to “011”, the “F” state corresponds to “001”, and the “G” state corresponds to “101”. When the 3-bit data is referred to as “abc”, “a” is referred to as an upper bit, “b” is referred to as a middle bit, and “c” is referred to as a lower bit. In this way, each memory cell can store data in accordance with a state to which the threshold voltage belongs. The correspondence relationship between the states and the data illustrated in FIG. 4 is an example of data coding. The data coding is not limited to the example of the drawing.

The threshold voltage can be lowered to the “Er” state by the erase operation. The threshold voltage can remain in the “Er” state or can be raised until the state reaches one of the “A” state, the “B” state, the “C” state, the “D” state, the “E” state, the “F” state, and the “G” state by the program operation.

Hereinafter, the memory cell in which the threshold voltage is set in a certain state by the program operation is referred to as a memory cell belonging to the state.

A read level that is a voltage for determining data is set between two adjacent states. For example, as exemplified in FIG. 4, a read level VA is set between the “Er” state and the “A” state, a read level VB is set between the “A” state and the “B” state, a read level VC is set between the “B” state and the “C” state, a read level VD is set between the “C” state and the “D” state, a read level VE is set between the “D” state and the “E” state, a read level VF is set between the “E” state and the “F” state, and a read level VG is set between the “F” state and the “G” state.

In the sensing operation, the processing circuit 210 sequentially applies the plurality of types of read levels to the select word line WL. For each memory cell, the processing circuit 210 determines in which state the memory cell is between a conductive state (in other words, an ON state) and a non-conductive state (in other words, an OFF state) when each read level is applied to the select word line WL. The processing circuit 210 determines data associated with the state to which the memory cell belongs to by a logical operation using a determination result obtained for each of the applied read levels. That is, the data is acquired based on comparison between the threshold voltage and a read level of each memory cell.

Hereinafter, an operation of applying a single type of read level VX (where X is one of A to G) to the select word line WL and determining, for each memory cell, in which state the memory cell is between the ON state and the OFF state is referred to as X reading or XR. A determination result of the X reading is referred to as a determination result XR.

The correspondence relationship between the states to which the threshold voltage of the memory cells belongs and the data stored in the memory cells when the data coding illustrated in FIG. 4 is adopted will be described. When the memory cell belongs to one of the “Er” state, the “E” state, the “F” state, and the “G” state, the lower bit of data stored in the memory cell is “1”. When the memory cell belongs to one of the “A” state, the “B” state, the “C” state, and the “D” state, the lower bit of data stored in the memory cell is “0”. Accordingly, the processing circuit 210 determines data of a lower page by using two types of read levels of VA and VE in the sensing operation on the lower page. That is, the processing circuit 210 determines the data of the lower page based on results of A reading and E reading.

When a memory cell belongs to one of the “Er” state, the “A” state, the “D” state, and the “E” state, the middle bit of the data stored in the memory cell is “1”. When a memory cell belongs to one of the “B” state, the “C” state, the “F” state, and the “G” state, the middle bit of the data stored in the memory cell is “0”. Accordingly, the processing circuit 210 determines data of the middle page by using three types of read levels of VB, VD, and VF in the sensing operation on the middle page. That is, the processing circuit 210 determines the data of the middle page based on results of B reading, D reading, and F reading.

When a memory cell belongs to one of the “Er” state, the “A” state, the “B” state, and the “G” state, the upper bit of the data stored in the memory cell is “1”. When a memory cell belongs to one of the “C” state, the “D” state, the “E” state, and the “F” state, the upper bit of the data stored in the memory cell is “0”. Accordingly, the processing circuit 210 determines data of the upper page by using two types of read levels of VC and VG in the sensing operation on the upper page. That is, the processing circuit 210 determines the data of the upper page based on results of C reading and G reading.

The sensing operation on each page is not limited to the above-described examples.

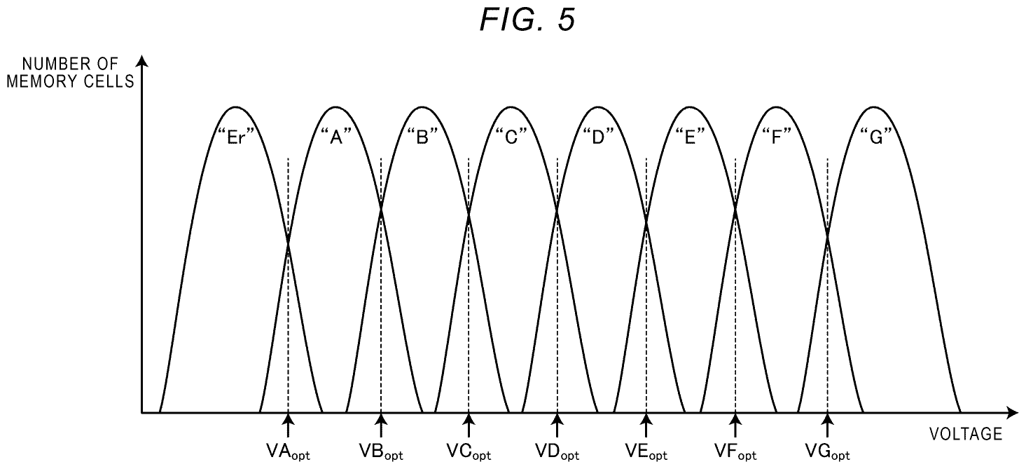

As described in FIG. 4, the memory cells form eight lobes that do not overlap each other. However, the threshold voltage of the memory cell changes in accordance with various factors. Accordingly, during the sensing operation, for example, as illustrated in FIG. 5, a part of one lobe between two adjacent lobes overlaps a part of the other lobe in some cases.

When the threshold voltage of the memory cell belonging to a certain state exceeds a read level corresponding to a boundary of the state and changes, a state of the memory cell that should be determined to be in the OFF state is determined to be the ON state or a state of the memory cell that should be determined to be in the ON state is conversely determined to be the OFF state. As a result, the data read from the memory cell may become erroneous. The number of erroneous bits included in the data read from a group of the memory cells is referred to as a fail bit count (FBC).

An error included in the data read from the NAND flash memory 200 is corrected by the ECC circuit 106. However, a large FBC increases a time required for the ECC circuit 106 to correct the error. In the worst case, an error correction failure is caused, which deteriorates quality of service (QoS). Accordingly, to improve performance of the memory system, it is necessary to identify a voltage value of a read level at which the FBC can be reduced most and perform a read operation using the voltage value of the read level. However, as described above, since the threshold voltage of the memory cell changes, the voltage value of the read level at which the FBC can be reduced most can also change.

To respond to a change in the threshold voltage of the memory cell, each memory chip CP is configured to allow the controller 100 to set a voltage value of each read level. For each read level, the controller 100 is configured to estimate and acquire a voltage value of a read level at which the FBC can be reduced most. The acquired voltage value of the read level is recorded in the management information 110. During a read operation, the controller 100 sets the voltage value recorded in the management information 110 in the memory chip CP so that the voltage value is used as a read level.

Various methods of setting the voltage value of the read level for each memory chip CP can be designed. For example, in each memory chip CP, an initial setting value is set in advance for each type of read levels, and the controller 100 may set a shift value from the initial setting value for the memory chip CP. In this case, the controller 100 sets a voltage value obtained by adding the shift value to the initial setting value as a read level. Alternatively, the controller 100 and each memory chip CP may be configured such that the controller 100 sets net voltage values for each type of read levels.

In the following description, the controller 100 is configured to record the shift value from the initial setting value for each type of read level in the management information 110 and set the shift value in the memory chip CP.

Each read level may be different for each unit storage area. The unit storage area is, for example, one memory cell group MCG, two or more memory cell groups MCG, a block BLK, a plurality of blocks BLK, the memory chip CP, or the like. When the shift value of each read level is different for each unit storage area, the shift values of various types of read levels are recorded for each unit storage area in the management information 110.

In the following description, a voltage value of a read level Vi (where i is A, B, C, D, E, F, or G) at which the FBC can be reduced most is referred to as an optimum read level Viₒₚₜ. When the types of read levels are not distinguished from each other, a read level at which the FBC is reduced most is referred to as an optimum read level. The read levels VA to VG used for determining data are referred to as actual read levels in order to distinguish the read levels VA to VG from reference read levels to be described below. The actual read level is an example of the actual read voltage, and the reference read level is an example of the reference read voltage.

A trigger for acquiring the optimum read level is not limited to a specific event. For example, the controller 100 may acquire an optimum read level in accordance with a result of error correction executed on data obtained in a read operation. More specifically, the controller 100 may acquire an optimum read level used for a read operation on the memory cell group MCG that stores data when error correction of the data read in the read operation fails. The controller 100 may execute the read operation on the memory cell group MCG again using the optimum read level obtained through the acquisition.

A voltage at which two adjacent lobes form an intersection is considered to correspond to an optimum read level. That is, as illustrated in FIG. 5, a voltage at an intersection between the lobe of the “Er” state and the lobe of the “A” state is an optimum read level VAₒₚₜ. A voltage at an intersection between the lobe of the “A” state and the lobe of the “B” state is an optimum read level VBₒₚₜ. A voltage at an intersection between the lobe of the “B” state and the lobe of the “C” state is an optimum read level VCₒₚₜ. A voltage at an intersection between the lobe of the “C” state and the lobe of the “D” state is an optimum read level VDₒₚₜ. A voltage at an intersection between the lobe of the “D” state and the lobe of the “E” state is an optimum read level VEₒₚₜ. A voltage at an intersection between the lobe of the “E” state and the lobe of the “F” state is an optimum read level VFₒₚₜ. A voltage at an intersection between the lobe of the “F” state and the lobe of the “G” state is an optimum read level VGₒₚₜ.

The controller 100 can execute a first acquisition operation of acquiring an optimum read level using a trained machine learning model and a second acquisition operation different from the first acquisition operation. In addition to the first and second acquisition operations, the controller 100 may execute a third acquisition operation different from the first and second acquisition operations as operations of acquiring the optimum read levels.

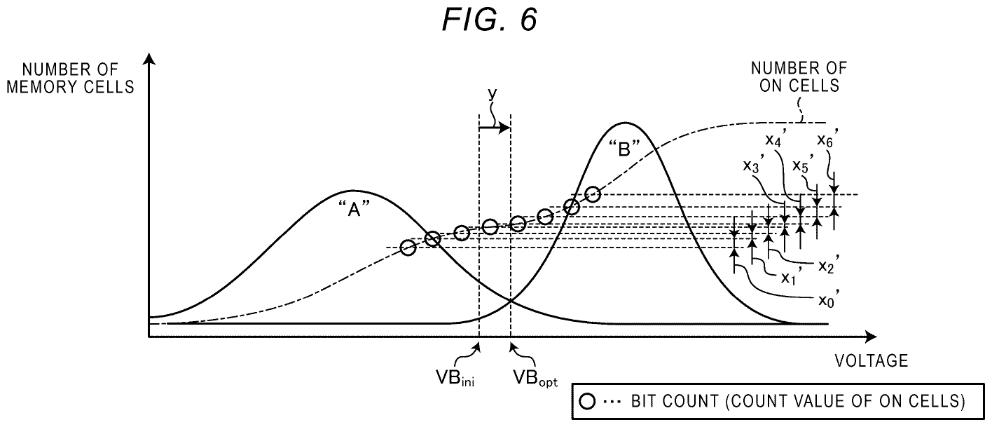

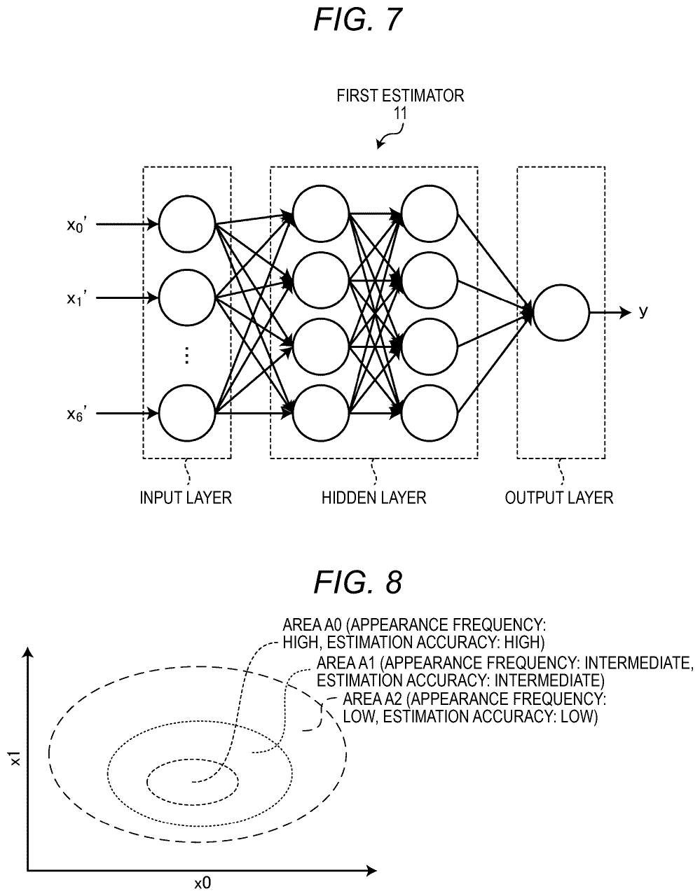

In the first acquisition operation, a first estimator (first estimator 11) is used as an example of the trained machine learning model. The first estimator 11 is a trained neural network model. A method of acquiring the optimum read levels using the first estimator 11 will be described with reference to FIGS. 6 and 7. The optimum read levels are acquired individually for each type of actual read levels. In the following description, a process in a case where an optimum read level XBₒₚₜ is an acquisition target will be described as an example.

FIG. 6 is a diagram illustrating a distribution of threshold voltages of the memory cells belonging to either the “A” state or the “B” state according to the first embodiment. In the drawing, VBᵢₙᵢ is an initial setting value of the read level VB. The read level VBᵢₙᵢ shifts from the optimum read level XBₒₚₜ. Accordingly, the controller 100 estimates a shift value y corresponding to the optimum read level XBₒₚₜ.

The controller 100 first executes a reference read operation. In the reference read operation, the controller 100 causes the processing circuit 210 to sequentially apply one or more voltage values within a voltage range that can include the optimum read level (here, the optimum read level XBₒₚₜ) to the word lines WL to which a certain memory cell group MCG is connected and to determine whether the memory cell is in the ON state or the OFF state for each memory cell in the memory cell group MCG. The controller 100 counts the number of memory cells that are in the ON state among the memory cells in the memory cell group MCG for each voltage value applied to the word line WL. Each of the plurality of voltage values applied to the word lines WL in the reference read operation is referred to as a reference read level. Hereinafter, the memory cell that is in the ON state is referred to as an ON cell. A count value of the ON cells obtained by the reference read operation is referred to as a bit count.

The number of memory cells in the memory cell group MCG is known. Accordingly, the controller 100 may be configured to count the memory cells that are in the OFF state instead of counting the ON cells.

One or more reference read levels used for the reference read operation are determined in accordance with, for example, the following method. Here, for example, it is assumed that eight different reference read levels are used in description.

When an acquisition target read level of the optimum read level is a read level corresponding to a boundary between an Mth state and an (M+1)th state from a low voltage side, the controller 100 regards a voltage value V_{base} closest to C_{MCG}*M/8 as a reference. The voltage value V_{base} is expressed as a DAC value. C_{MCG} is the number of memory cells in one memory cell group MCG. The controller 100 selects eight voltage values at predetermined intervals (here, for example, 4 DAC) on positive and negative sides from the voltage value V_{base}, that is, V_{base}−16, V_{base}−12, V_{base}−8, V_{base}−4, V_{base}, V_{base}+4, V_{base}+8, and V_{base}+12, and sets the selected eight voltage values as reference read levels.

A method of determining the reference read levels is not limited thereto. The reference read level may be given in advance for each type of read level by a designer. When a minimum value of the actual read level is determined for each type of actual read level, the controller 100 may determine a plurality of voltage values selected at the predetermined interval in an ascending order as reference read levels using the minimum value of the actual read level as a reference.

In the example illustrated in FIG. 6, a one-dot chain line indicates the number of ON cells for the reference read levels. The controller 100 sequentially uses eight different reference read levels by the reference read operation, and the controller 100 acquires the bit count at points shown in eight circular shapes on the one-dot chain lines illustrated in FIG. 6. The controller 100 calculates a difference bit count group x′ in which differences of bit counts obtained at two adjacent reference read levels are collected. Here, since the eight reference read levels are used, the difference bit count group x′ includes seven elements. The seven elements included in the difference bit count group x′ are referred to as x₀′, x₁′, x₂′, x₃′, x₄′, x₅′, and x₆′ in order of voltages of pairs of adjacent reference read levels.

The difference bit count group x′ is considered to be an example of a histogram of the number of memory cells in which a threshold voltage is included in each of the plurality of voltage intervals partitioned by one or more reference read levels. The histogram is an example of a data set corresponding to a distribution of the threshold voltages of the memory cells.

When the difference bit count group x′ is input, the first estimator 11 is configured to output an estimated value of the optimum read level VBₒₚₜ as the reference y using the initial setting value (that is, the read level VBᵢₙᵢ) as a reference. The difference y is a shift value.

FIG. 7 is a diagram illustrating an example of a configuration of the first estimator 11 according to the first embodiment.

The first estimator 11 has a configuration of a multi-layer perceptron (MLP) that has one or more hidden layers. The first estimator 11 may have a fully connected MLP or may have a sparsely connected MLP.

In the example illustrated in FIG. 7, the first estimator 11 has an input layer, two hidden layers, and an output layer. The input layer has seven nodes to which different elements included in the difference bit count group x′ are input. Each of the two hidden layers has four nodes. The output layer has one node that outputs the shift value y. The node can also be referred to as a neuron.

In the hidden layers and the output layer, each node multiplies each input value from a node of a previous layer by a weight, applies an activation function to a total sum of a bias and each value after being multiplied by the weight, and outputs a value obtained by applying the activation function.

The bias and the weight are determined in advance by training. That is, the first estimator 11 is trained in advance to map the difference bit count group x′ to the shift value y.

The above-described configuration of the first estimator 11 is recorded in the first estimator information 111. The first estimator information 111 includes, for example, definition of the plurality of nodes and definition of a connection relationship between the nodes. In the first estimator information 111, the activation function, the trained bias, and the trained weight are associated with each node.

The first estimator information 111 is stored in advance at a predetermined location in, for example, the NAND flash memory 200. For example, when the memory system 1 is started up, the CPU 102 loads the first estimator information 111 to the RAM 104. Based on the first estimator information 111 loaded to the RAM 104, the CPU 102 implements calculation of the first estimator 11 by executing calculation that is based on the weight, the bias, and the activation function associated with each node.

In general, the neural network model can handle a nonlinear relationship between a description variable and an objective variable with high accuracy. On the other hand, in the neural network model, an unexpected large estimation error may arise in a sample drawn from data used for training and different populations.

Accordingly, in the first embodiment, the controller 100 calculates a confidence level c as an index indicating accuracy of estimation based on whether the difference bit count group x′ is close to a group of data used for training of the first estimator 11. Based on the confidence level c, the controller 100 determines whether to adopt the shift value y acquired by the first acquisition operation, that is, the shift value y output from the first estimator 11. Accordingly, the voltage value including a large estimation error is prevented from being used as the actual read level.

Training data of the first estimator 11 is generated as follows, for example. Sample products of one or more memory chips CP are connected to a test device. The test device executes a test for simulating actual use of the memory system 1 for the sample product. The test device acquires many pairs of difference bit count groups x and the optimum read levels from the sample products. The difference bit count group x is acquired in accordance with a similar method with that of the difference bit count group x′. Accordingly, the difference bit count group x includes seven elements like the difference bit count group x′. The seven elements included in the difference bit count group x are referred to as x₀, x₁, x₂, x₃, x₄, x₅, and x₆ in order of voltages of pairs of adjacent reference read levels. Any method of acquiring optimum read levels from the sample products can be used as long as very appropriate values can be acquired. The pairs of difference bit count groups x and the optimum read levels are considered to be training data. Many pieces of training data are generated while changing conditions of the test variously.

FIG. 8 is a diagram illustrating an example of an appearance frequency of the difference bit count group x included in each piece of training data according to the first embodiment. In description of the drawing, to prevent the drawing from being complex, the difference bit count group x is formed by two elements, that is, x₀ and x₁, and a distribution of an appearance frequency of the difference bit count group x is displayed on an x₀x₁ plane. In the following description, the appearance frequency of the difference bit count group x is simply referred to as an appearance frequency.

An area A0 is an area where the appearance frequency is high. An area A2 is an area where the appearance frequency is low. The area A1 is an area where the appearance frequency is higher than the appearance frequency in the area A2 and is lower than that in the area A1.

For example, when the difference bit count group x′ is included in the area A0, highly accurate estimation can be executed using the first estimator 11. When the difference bit count group x′ is included in the area A1, highly accurate estimation is possible second to estimation when the difference bit count group x′ is included in the area A0. When the difference bit count group x′ is included in the area A2, accuracy of estimation is lower than when the difference bit count group x′ is included in the area A1. In this way, the accuracy of the estimation by the first estimator 11 relates to the appearance frequency of the difference bit count group x.

For example, the confidence level c is a value that falls within an interval of 0 to 1. The confidence level c takes a large value depending on the appearance frequency of the difference bit count group x at a location of the difference bit count group x′. A calculation method for the confidence level c is defined so that the confidence level c is closer to 1 as the appearance frequency of the difference bit count group x at the location of the difference bit count group x′ is higher, and the confidence level c is closer to 0 as the appearance frequency of the difference bit count group x at the location of the difference bit count group x′ is lower.

In the first embodiment, the controller 100 calculates the confidence level c using a second estimator (second estimator 12) that is a trained neural network model.

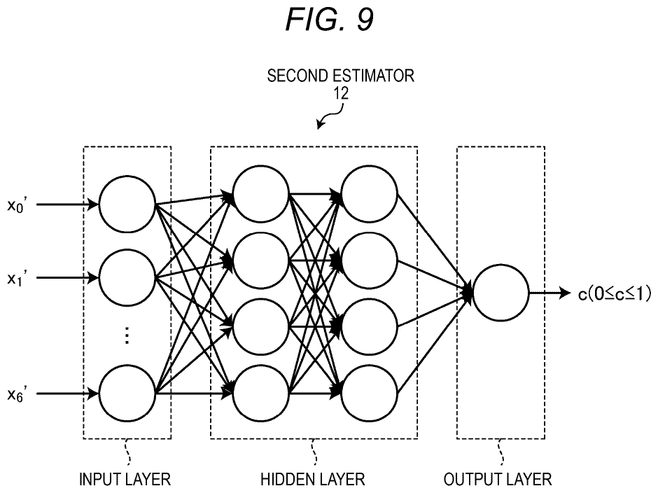

FIG. 9 is a diagram illustrating an example of a configuration of the second estimator 12 according to the first embodiment.

The second estimator 12 has a configuration of an MLP that has one or more hidden layers. The first estimator 11 may have a fully connected MLP or may have a sparsely connected MLP.

In the example illustrated in FIG. 9, the second estimator 12 has an input layer, two hidden layers, and an output layer. The input layer has seven nodes to which different elements included in the difference bit count group x′ are input. Each of the two hidden layers has four nodes. The output layer has one node that outputs the confidence level c.

In the hidden layers and the output layer, each node multiplies each input value from a node of a previous layer by a weight, applies an activation function to a total sum of a bias and each value after being multiplied by the weight, and outputs a value obtained by applying the activation function.

The bias and the weight are determined in advance by training. That is, the second estimator 12 is trained in advance to map the difference bit count group x′ to the confidence level c.

The above-described configuration of the second estimator 12 is recorded in the second estimator information 112. The second estimator information 112 includes, for example, definition of the plurality of nodes, definition of a connection relationship between the nodes, and the bias. In the second estimator information 112, the activation function, the trained bias, and the trained weight are associated with each node.

The second estimator information 112 is stored in advance at a predetermined location in, for example, the NAND flash memory 200. For example, when the memory system 1 is started up, the CPU 102 loads the second estimator information 112 to the RAM 104. Based on the second estimator information 112 loaded to the RAM 104, the CPU 102 implements calculation of the second estimator 12 by executing calculation that is based on the weight, the bias, and the activation function associated with each node.

In the example illustrated in FIG. 9, a node configuration of the second estimator 12 is the same as the node configuration of the first estimator 11. The node configuration of the second estimator 12 may be different from the node configuration of the first estimator 11.

The controller 100 compares a threshold Th1 set in advance to correspond to the appearance frequency at which sufficient estimation accuracy can be obtained with the confidence level C.

When the confidence level c is greater than the threshold Th1, the difference bit count group x′ can be considered to be included in an area where the appearance frequency of the difference bit count group x is high (which is referred to as a first area). The appearance frequency of the difference bit count group x in the first area is higher than the appearance frequency at which sufficient estimation accuracy can be obtained. Accordingly, the controller 100 adopts the shift value y acquired by the first acquisition operation.

When the confidence level c is less than the predetermined threshold Th1, the difference bit count group x′ can be considered to be included in an area where the appearance frequency of the difference bit count group x is low (which is referred to as a second area). The appearance frequency of the difference bit count group x in the second area is lower than the appearance frequency at which sufficient estimation accuracy can be obtained. Accordingly, the controller 100 does not adopt the shift value y acquired by the first acquisition operation. The controller 100 acquires the shift value y by the second acquisition operation and adopts the shift value y acquired by the second acquisition operation.

When the confidence level c is equal to the threshold Th1, the controller 100 may adopt the shift value y acquired by the first acquisition operation or may adopt the shift value y acquired by the second acquisition operation. Hereinafter, for example, when the confidence level c is equal to the threshold Th1, the controller 100 is assumed to adopt the shift value y acquired by the second acquisition operation.

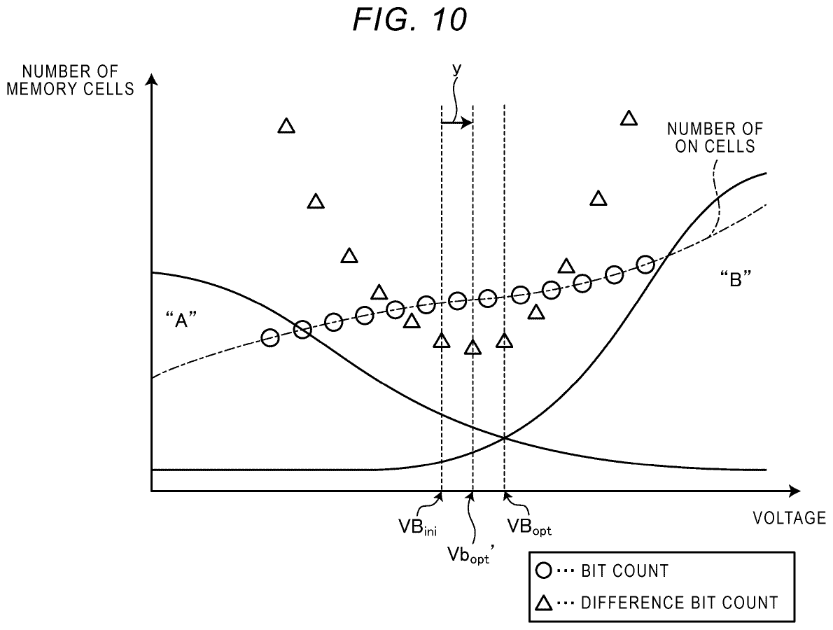

FIG. 10 is a diagram illustrating an example of the second acquisition operation according to the first embodiment. In the drawing, a distribution of the memory cells belonging to either the “A” state or the “B” state and a transition of the number of ON cells are illustrated.

The controller acquires bit counts of a plurality of points within a voltage range that can include the optimum read levels VBₒₚₜ by a similar operation to the reference read operation. The controller 100 calculates the difference bit counts of the plurality of points from the bit counts of the plurality of points. The controller 100 may also use the difference bit count group x′ acquired for estimation using the first estimator 11 as the different bit counts of the plurality of points by the second acquisition operation. Based on the difference bit counts of the plurality of points, the controller 100 views a voltage value at which the difference bit count is taken as a minimum value as an estimated value (written as VBₒₚₜ′) of the optimum read level VBₒₚₜ. The controller 100 may fit the difference bit counts of the plurality of points to a predetermined curve by, for example, the least squares method or the like and may identify the voltage value at which the difference bit count takes a minimum value based on the curve. The controller 100 acquires a difference between the estimated value VBₒₚₜ′ and the initial setting value VBᵢₙᵢ as a shift value y.

An example of the second acquisition operation described with reference to FIG. 10 is referred to as a minimum value scheme. In some cases, the accuracy of the estimation at the optimum read level by the minimum value scheme is not higher as the accuracy of the estimation by a scheme using the foregoing neural network model (that is, the first estimator 11). According to the minimum value scheme, however, unlike the scheme of the estimation in which the first estimator 11 is used, the optimum read levels can be estimated without considerably worsening the accuracy of the estimation in any situation.

As the second acquisition operation, any scheme can be applied other than the minimum value scheme. As another applicable example of the second acquisition operation, a median tracking scheme will be described.

In the TLC mode, the memory cell can take eight states. In many use cases, a group of programmed memory cells is substantially equally partitioned into eight states. That is, it can be considered that the memory cells corresponding to ⅛ of the group of the programmed memory cell belong to any state. Accordingly, as the median tracking scheme, the controller 100 acquires seven voltage values, each separated by ⅛ of the number of ON cells for the memory cells included in a certain set (for example, one memory cell group MCG), as estimated values of seven types of optimum read levels. In this way, according to the median tracking scheme, the optimum read levels are estimated based on the number of states that can be taken and the number of ON cells. According to the median tracking scheme, like the minimum value scheme, the optimum read levels can be estimated with stable accuracy even in any situation.

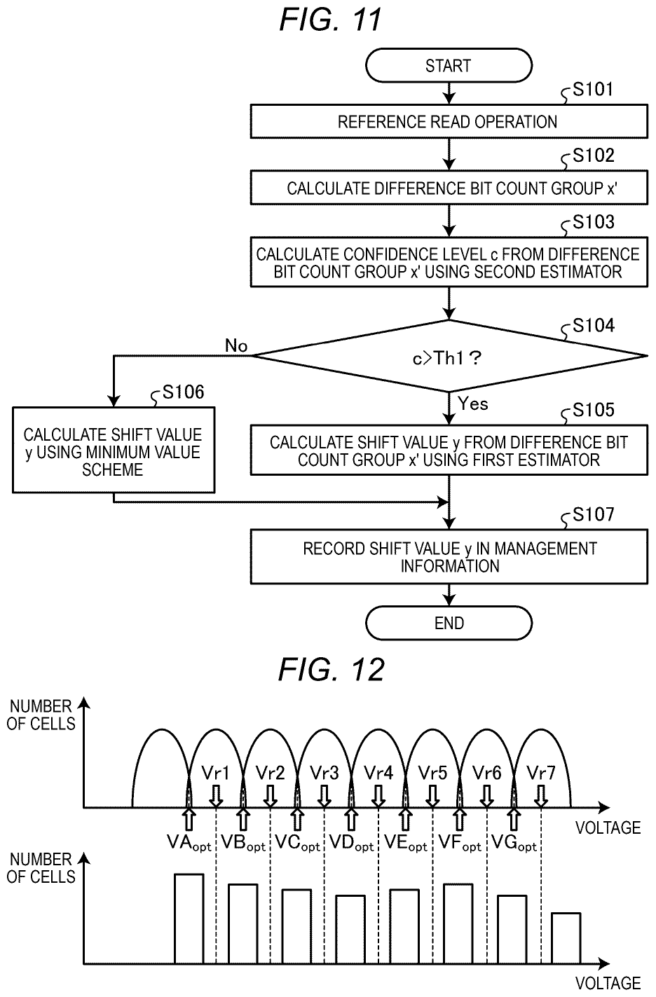

FIG. 11 is a flowchart illustrating an example of an operation of the memory system 1 according to the first embodiment.

The controller 100 first executes the reference read operation (S101).

The controller 100 calculates the difference bit count group x′ based on the bit count obtained for each reference read level by the process of S101 (S102).

The controller 100 calculates the confidence level c from the difference bit count group x′ using the second estimator 12 (S103). In S103, the controller 100 inputs the difference bit count group x′ to the input layer of the second estimator 12 and acquires a value output from the output layer of the second estimator 12 as the confidence level c in response to the input of the difference bit count group x′.

The controller 100 determines whether the confidence level c is greater than the threshold Th1 (S104).

When the confidence level c is greater than the threshold Th1 (Yes in S104), the controller 100 calculates the shift value y from the difference bit count group x′ using the first estimator 11 (S105).

When the confidence level c is not greater than the threshold Th1 (No in S104), the controller 100 calculates the shift value y using the minimum value scheme (S106).

After S105 or S106, the controller 100 records the shift value y in the management information 110 (S107). Then, the series of operations ends.

In this way, the controller 100 acquires the difference bit count group x′ by executing reading using the plurality of reference read levels (for example, see of FIGS. 6 and S101 and S102 of FIG. 11). The controller 100 selects one acquisition operation among the plurality of acquisition operations of acquiring the reference read levels based on the difference bit count group x′ (for example, see S103 to S106 of FIG. 11). The plurality of acquisition operations include the first acquisition operation of acquiring the optimum read levels using the first estimator 11 that is an example of a trained machine learning model and the second acquisition operation different from the first acquisition operation. The controller 100 executes reading using the acquired reference read levels.

More specifically, the controller 100 inputs the difference bit count group x′ to the second estimator 12 that is a trained machine learning model. Based on an output value from the second estimator 12, the controller 100 determines whether the difference bit count group x′ is included in an area where the appearance frequency of the difference bit count group x is high or an area where the appearance frequency of the difference bit count group x is low (for example, see FIGS. 8 and 9, and S103 and S104 of FIG. 11). When the difference bit count group x′ is included in the area where the appearance frequency of the difference bit count group x is high, the controller 100 selects the first acquisition operation (for example, see S105 of FIG. 11). When the difference bit count group x′ is included in an area where the appearance frequency of the difference bit count group x is low, the controller 100 selects the second acquisition operation (for example, see S106 of FIG. 11).

Accordingly, it is possible to curb deterioration in the estimation accuracy of the optimum read levels due to an unexpected estimation error of a machine learning model. It is possible to provide the memory system 1 with high performance since the optimum read levels can be estimated with high accuracy.

### First Further Embodiment of the First Embodiment

In the first embodiment, the first estimator 11 that is the neural network model is used to estimate the optimum read levels. In the estimation of the optimum read levels, any machine learning model can be used other than the neural network model. As a further embodiment of the first embodiment, a configuration for estimating the optimum read levels using matrix calculation instead of the first estimator 11 will be described.

The controller 100 executes a read operation similar to the reference read operation using voltage values Vr of a plurality of points selected from an entire range in which the threshold voltage can be taken. The controller 100 sets a plurality of intervals partitioned by the used voltage values of the plurality of points as bins and generates a histogram (referred to as a histogram 400) in which the number of memory cells is a frequency.

For example, in the example illustrated in the upper side of FIG. 12, bit counts are acquired using voltage values Vr1, Vr2, Vr3, Vr4, Vr5, Vr6, and Vr7 of seven points selected from the entire range in which eight lobes are distributed. For example, the histogram 400 that has eight bins as illustrated in the lower side of FIG. 12 is generated based on the bit count acquired for each voltage value. The histogram is another example of the data set corresponding to the distribution of the threshold voltages of the memory cells.

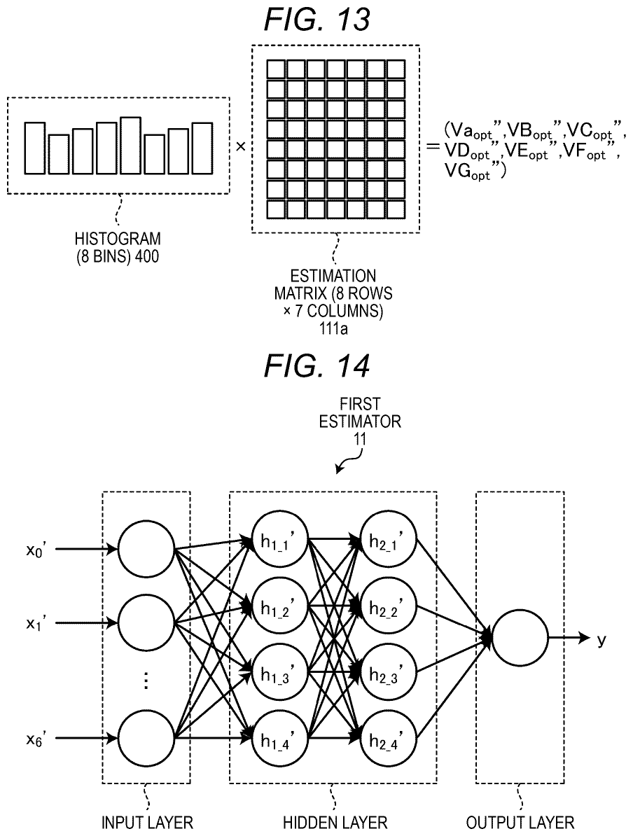

FIG. 13 is a diagram illustrating calculation for estimating optimum read level using the estimation matrix according to the first further embodiment of the first embodiment.

In the RAM 104, an estimation matrix 111a is stored instead of the first estimator information 111. The estimation matrix 111a has the same number of rows as the number of bins of the histogram 400 and the same number of columns as the number of all kinds of read levels. The estimation matrix 111a is trained in advance to map the histogram 400 to all kinds of optimum read levels. The controller 100 views a group of voltage values VAₒₚₜ″, VBₒₚₜ″, VCₒₚₜ″, VDₒₚₜ″, VEₒₚₜ″, VFₒₚₜ″, and VGₒₚₜ″ obtained by applying the estimation matrix 111a to the histogram 400, as a group of estimated values of the optimum read levels.

The estimation matrix 111a may be configured so that a shift value is output for each type of read level.

When the estimation matrix 111a is applied to the estimation of the optimum read levels, the second estimator 12 is configured to be able to acquire the confidence level c from the histogram 400.

### Second Embodiment

In the first embodiment, the confidence level c is calculated using the second estimator 12 and the acquisition operation is selected based on the confidence level c. A method of selecting the acquisition operation is not limited thereto. In a second embodiment, another example of a method of selecting an acquisition operation will be described. In the second embodiment, factors different from those of the first embodiment will be described. The same factors as those of the first embodiment will not be described or described briefly.

In the second embodiment, the controller 100 selects an acquisition operation based on a node value of the first estimator 11 when the difference bit count x′ is input.

FIG. 14 is a diagram illustrating a node value of the first estimator 11 according to the second embodiment.

As described above, each node multiplies each input value from a node of a previous layer by a weight, applies an activation function to a total sum of a bias and each value after being multiplied by the weight, and outputs a value obtained by applying the activation function. The node value is a value output by the node, that is, a value immediately after the activation function is applied.

The controller 100 inputs the difference bit count group x′ to the first estimator 11 and acquires the node values of some or all of the nodes included in the first estimator 11 when the shift value y is output from the difference bit count group x′. Here, for example, the controller 100 acquires a node value of each node forming the hidden layers.

A node value of a qth node of a hidden layer of a pth layer from the input layer, which is acquired in response to an input of the difference bit count group x′ is written as h_{p_q}′. In the example illustrated in FIG. 14, eight node values h_{1_1}′, h_{1_2}′, h_{1_3}′, h_{1_4}′, h_{2_1}′, h_{2_2}′, h_{2_3}′, and h_{2_4}′ are acquired. The eight node values h_{1_1}′, h_{1_2}′, h_{1_3}′, h_{1_4}′, h_{2_1}′, h_{2_2}′, h_{2_3}′, and h_{2_4}′ are generally referred to as node values h′.

For all the acquisition target nodes of the node values h′, minimum and maximum values are defined in advance individually for each node. The controller 100 compares each of all the acquired node values h′ with the minimum and maximum values of the corresponding node. When each of all the acquired node values h′ falls within an interval between the minimum and maximum values of the corresponding node, the controller 100 selects the first acquisition operation. When there is the node value h′ that does not fall within the interval between the minimum and maximum values of the corresponding node among all the acquired node values h′, the controller 100 selects the second acquisition operation.

The minimum and maximum values of the node values are determined as follows, for example, in a manufacturing process or the like. That is, whenever the difference bit count group x included in the training data is input to the first estimator 11, node values (written as h_{p_q}) of all the acquisition target nodes of the node values h′ are collected. For each node, a minimum value min(h_{p_q}) of the node value h_{p_q} and a maximum value max(h_{p_q}) of the node value h_{p_q} are acquired. The controller 100 uses the minimum value min(h_{p_q}) and the maximum value max(h_{p_q}) as minimum and maximum values to be compared with the node value h_{p_q}′.

When the node value h_{p_q}′ of each node falls between the minimum value min(h_{p_q}) and the maximum value max(h_{p_q}), it is considered that the difference bit count group x′ is included in an area where the appearance frequency of the difference bit count group x is high. Accordingly, when the node value h_{p_q}′ of each node falls between the minimum value min(h_{p_q}) and the maximum value max(h_{p_q}), the controller 100 selects the first acquisition operation. When the node value h_{p_q}′ of any node does not fall between the minimum value min(h_{p_q}) and the maximum value max(h_{p_q}), the controller 100 selects the second acquisition operation.

Any process when the node value h_{p_q}′ is equal to the minimum value min(h_{p_q}) or the maximum value max(h_{p_q}) is executed. When the node value h_{p_q}′ is equal to the minimum value min(h_{p_q}) or the maximum value max(h_{p_q}), the controller 100 may consider that the node value h_{p_q}′ falls between the minimum value min(h_{p_q}) and the maximum value max(h_{p_q}) or may consider that the node value h_{p_q}′ does not fall between the minimum value min(h_{p_q}) and the maximum value max(h_{p_q}).

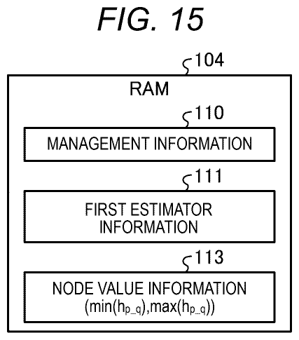

FIG. 15 is a diagram illustrating information to be stored in the RAM 104 according to the second embodiment. As illustrated in the drawing, node value information 113 is stored in the RAM 104 instead of the second estimator information 112. The node value information 113 is information in which the minimum value min(h_{p_q}) and the maximum value max(h_{p_q}) are recorded for each acquisition target node of the node value h′. The node value information 113 is stored in advance at a predetermined location in, for example, the NAND flash memory 200. When the memory system 1 is started up, the CPU 102 loads the node value information 113 to the RAM 104. The CPU 102 uses the node value information 113 loaded to the RAM 104 for an operation of estimating the optimum read levels.

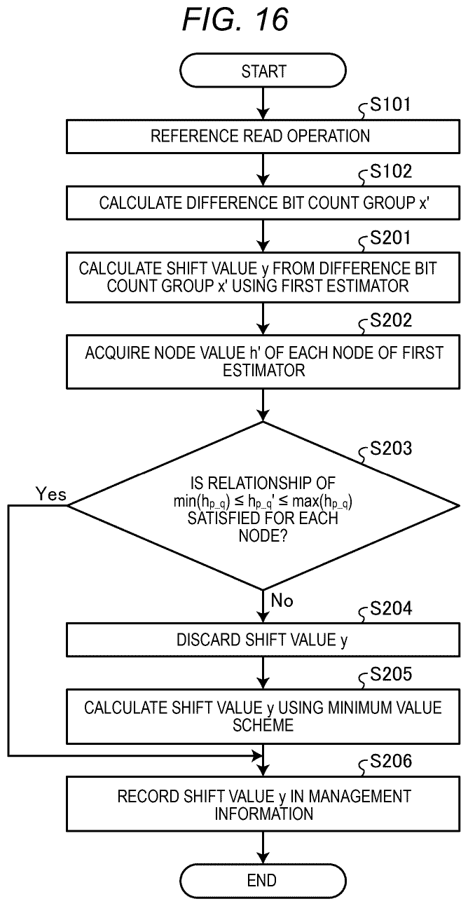

FIG. 16 is a flowchart illustrating an example of an operation of the memory system 1 according to the second embodiment.

The controller 100 first executes the above-described processes of S101 and S102.

When the process of S102, that is, the calculation of the difference bit count group x′ using the first estimator 11, is completed, the shift value y is calculated from the difference bit count group x′ using the first estimator 11 (S201). Then, the controller 100 acquires the node value h_{p_q}′ of each node of the first estimator 11 (S202).

The controller 100 determines whether a relationship of the following Formula (1) is satisfied in each node in which the node value h_{p_q}′ is acquired (S203).

$$min ( {h}_{p \_ q} ) \leq {h}_{p \_ q}^{′} \leq max ( {h}_{p \_ q} ) \qquad ( 1 )$$

When the relationship of Formula (1) is not satisfied for any node in which the node value h_{p_q}′ is acquired (No in S203), the controller 100 discards the shift value y obtained by the process of S201 (S204) and calculates the shift value y using the minimum value scheme (S205). The controller 100 records the shift value y in the management information 110 (S206). Then, the series of operations ends.

When the relationship of Formula (1) is satisfied for all nodes in which the node value h_{p_q}′ is acquired (YES in S203), the controller 100 skips the processes of S204 and S205 and executes the process of S206.

As described above, the controller 100 inputs the difference bit count group x′ to the first estimator 11, inputs the difference bit count group x′ to the first model, and acquires the node value of the node of the first estimator 11 when the difference bit count group x′ is input (for example, see S201 and S202 of FIG. 16). Based on the node value, the controller 100 determines whether the difference bit count group x′ is included in an area where the appearance frequency of the difference bit count group x is high or an area where the appearance frequency of the difference bit count group x is low (for example, see S203 of FIG. 16).

More specifically, when the node value of the node of the first estimator 11 during inputting of the difference bit count group x′ to the first estimator 11 is greater than the minimum value and less than the maximum value, the controller 100 selects the first acquisition operation. When the node value of the node of the first estimator 11 during inputting of the difference bit count group x′ to the first estimator 11 is less than the minimum value and greater than the maximum value, the controller 100 selects the second acquisition operation.

In this way, when the first estimator 11 is a neural network model, the acquisition operation can be selected based on the node value of the node of the first estimator 11.

### First Further Embodiment of the First Embodiment

Instead of the node values of the nodes forming the hidden layers of the first estimator 11, a value input to the first estimator 11, that is, the difference bit count group x′, may be used to determine whether to select the first acquisition operation.

When the difference bit count group x′ is used to determine whether to select the first acquisition operation, for example, the minimum and maximum values of the difference bit count group x are recorded in advance in the node value information 113 for each element of the difference bit count group x. When values of all the elements of the difference bit count group x′ fall within an interval between the minimum and maximum values, the controller 100 adopts estimation results of the optimum read levels in which the first estimator 11 is used. When the value of any element of the difference bit count group x′ does not fall within the interval between the minimum and maximum values, the controller 100 does not adopt the estimation results of the optimum read levels in which the first estimator 11 is used.

The first further embodiment of the second embodiment is not limited to the first estimator 11 in which the neural network model is adopted and can also be applied to any system that estimates the optimum read levels using a machine learning model. That is, the first further embodiment of the second embodiment can also be used with the first further embodiment of the first embodiment.

### Second Further Embodiment of the Second Embodiment

The controller 100 may determine whether to select the first acquisition operation using an average and a dispersion of the node values h_{p_q} instead of the minimum and maximum values of the node values h_{p_q}.

For example, lower and upper limits calculated based on a standard deviation σ from an average of the node values h_{p_q} are recorded in advance for each node in the node value information 113. For example, the lower limit is a value obtained by subtracting cₐ*σ (where cₐ is a constant) from the average and the upper limit is a value obtained by adding cₐ*σ to the average. The controller 100 uses the lower and upper limits instead of the minimum value min(h_{p_q}) and the maximum value max(h_{p_q}) of the node values h_{p_q} in the process of S203.

The controller 100 may be configured to determine whether to select the first acquisition operation based on an Lp norm of the node values h_{p_q}′ up to a group of the node values h_{p_q}. For example, the controller 100 calculates the Lp norm for each node. When all the calculated Lp norms are less than a predetermined threshold, the controller 100 selects the first acquisition operation. When there is the node in which the Lp norm is greater than the predetermined threshold, the controller 100 selects the second acquisition operation.

The second further embodiment of the second embodiment can also be applied to the first further embodiment of the second embodiment by replacing the node values h_{p_q}′ with the elements of the difference bit count group x′.

### Third Embodiment

Memory cells are subjected to various types of stress depending on access patterns to the memory chips CP. As the stress given to the memory cells, Read Disturb (RD), Cross Temperature (CT), Data Retention (DR), and the like are known. Read Disturb is a phenomenon where the threshold voltage of a memory cell included in a string unit SU is changed to a high voltage side whenever a sensing operation is executed on the string unit SU. Cross Temperature indicates a difference between a temperature in a program operation and a temperature in a sensing operation. Data Retention is a phenomenon where the threshold voltage of the memory cell is changed to a low voltage side over time after the program operation is executed on the memory cell. The optimum read level can change differently depending on the types of stress.

A test device collects a group of training data while variously changing stress given to a sample product in some cases. In these cases, two or more areas where the appearance frequency is high may appear or a large area in which the appearance frequency is high and which has a distorted shape in which two small areas where the appearance frequency is high are connected may appear.

In a third embodiment, a group of training data is classified into a plurality of small groups depending on a type of stress, and the minimum value min(h_{p_q}) and the maximum value max(h_{p_q}) are acquired in advance for each small group. Based on the minimum value min(h_{p_q}) and the maximum value max(h_{p_q}) acquired for each small group, the controller 100 determines whether to adopt estimation results of the optimum read levels using the first estimator 11. Hereinafter, factors different from those of the second embodiment will be described. The same factors as those of the second embodiment will not be described.

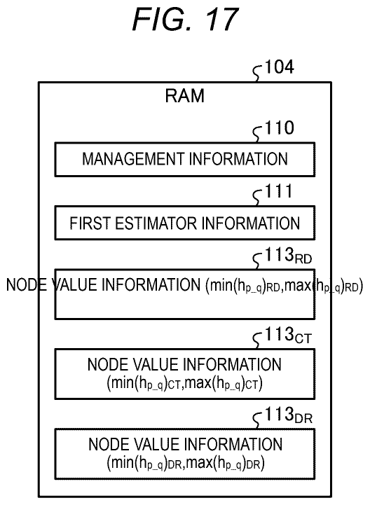

FIG. 17 is a diagram illustrating information stored in the RAM 104 according to the third embodiment. As illustrated in the drawing, node value information 113_{RD}, node value information 113_{CT}, and node value information 113_{DR} are stored in the RAM 104 instead of the node value information 113.

The node value information 113_{RD} is information in which a minimum value (written as min(h_{p_q})_{RD}) and a maximum value (written as max(h_{p_q})_{RD}) of the node value h_{p_q} obtained from a small group of the difference bit count group x collected in a test in which stress of Data Retention is given to a sample product are recorded for each node.

The node value information 113_{CT} is information in which a minimum value (written as min(h_{p_q})_{CT}) and a maximum value (written as max(h_{p_q})_{CT}) of the node value h_{p_q} obtained from a small group of the difference bit count group x collected in a test in which stress of Cross Temperature is given to a sample product are recorded for each node.

The node value information 113_{DR} is information in which a minimum value (written as min(h_{p_q})_{DR}) and a maximum value (written as max(h_{p_q})_{DR}) of the node value h_{p_q} obtained from a small group of the difference bit count group x collected in a test in which stress of Data Retention is given to a sample product are recorded for each node.

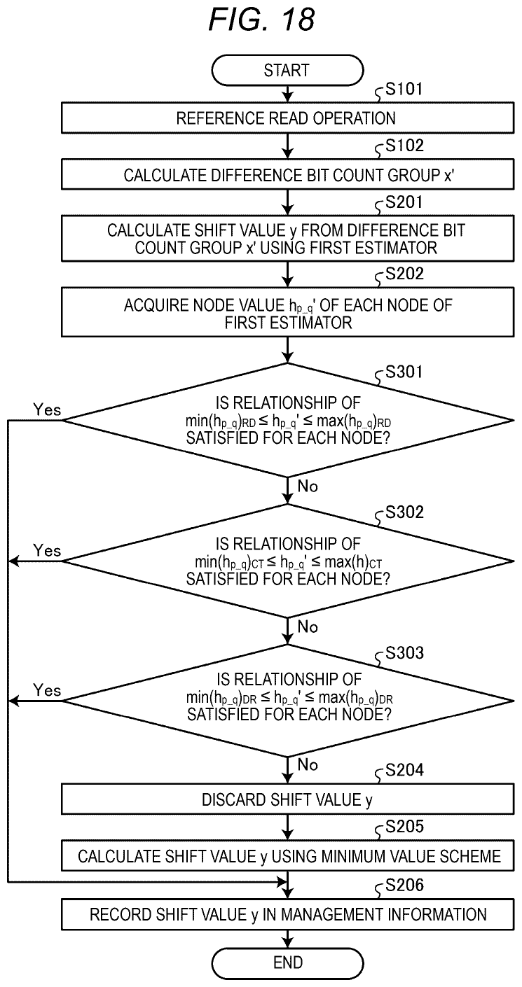

FIG. 18 is a flowchart illustrating an example of an operation of the memory system 1 according to the third embodiment.

The controller 100 first executes the processes of S101, S102, S201, and S202 described above.

After the process of S202, the controller 100 determines whether the relationship of the following Formula (2) is satisfied in all the nodes in which the node values h_{p_q}′ are acquired (S301).

$${min ( {h}_{p \_ q} )}_{R D} \leq {h}_{p \_ q}^{′} \leq {max ( {h}_{p \_ q} )}_{R D} \qquad ( 2 )$$

When the relationship of Formula (2) is not satisfied for any node in which the node value h_{p_q}′ is acquired (No in S301), the controller 100 determines whether the relationship of the following Formula (3) is satisfied in all the nodes in which the node values h_{p_q}′ are acquired (S302).

$${min ( {h}_{p \_ q} )}_{C T} \leq {h}_{p \_ q}^{′} \leq {max ( {h}_{p \_ q} )}_{C T} \qquad ( 3 )$$

When the relationship of Formula (3) is not satisfied for any node in which the node value h_{p_q}′ is acquired (No in S302), the controller 100 determines whether the relationship of the following Formula (4) is satisfied in all the nodes in which the node values h_{p_q}′ are acquired (S303).

$${min ( {h}_{p \_ q} )}_{D R} \leq {h}_{p \_ q}^{′} \leq {max ( {h}_{p \_ q} )}_{D R} \qquad ( 4 )$$

When the relationship of Formula (4) is not satisfied for any node in which the node value h_{p_q}′ is acquired (No in S303), the controller 100 executes the processes of S204 to S206 and ends the series of operations.

When the relationship of Formula (2) is satisfied in all the nodes in which the node values h_{p_q}′ are acquired (Yes in S301), the relationship of Formula (3) is satisfied in all the nodes in which the node values h_{p_q}′ are acquired (Yes in S302), or the relationship of Formula (4) is satisfied in all the nodes in which the node values h_{p_q}′ are acquired (Yes in S303), the controller 100 executes the process of S206 and ends the series of operations.

In the above description, a group of the training data is classified into a plurality of small groups depending on a type of stress given to a sample product when the training data is obtained. A classification method is not limited thereto. For example, the group of the training data may be classified into the plurality of small groups depending on a clustering scheme based on a mutual distance.

As described above, according to the third embodiment, the controller 100 is configured to compare the node value h′ in each of the plurality of small groups with the minimum and maximum values.

Accordingly, even when the number of areas where the appearance frequency is high is two or more or the shape of an area where the appearance frequency is high is distorted, the optimum read levels can be estimated with high accuracy.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory system comprising:
a plurality of memory cells; and
a controller configured to:
acquire a data set corresponding to a distribution of threshold voltages of the plurality of memory cells by reading the plurality of memory cells using a reference read voltage;
select one from a plurality of acquisition operations of acquiring an actual read voltage for reading data stored in the plurality of memory cells based on the data set, wherein the plurality of acquisition operations include a first acquisition operation of acquiring the actual read voltage from the data set using a first trained machine learning model and a second acquisition operation different from the first acquisition operation; and
acquire the actual read voltage using the selected acquisition operation and read the plurality of memory cells using the acquired actual read voltage.

2. The memory system according to claim 1, wherein
the controller is further configured to:
determine whether the data set is included in a first area or a second area based on the data set;
select the first acquisition operation when the data set is included in the first area; and
select the second acquisition operation when the data set is included in the second area, wherein
an appearance frequency of training data of the first trained machine learning model in the first area is higher than an appearance frequency of training data of the first trained machine learning model in the second area.

3. The memory system according to claim 2, wherein the controller is further configured to:
input the data set to a second trained machine learning model; and
determine whether the data set is included in the first area or the second area based on an output value from the second trained machine learning model.

4. The memory system according to claim 2,
wherein the first trained machine learning model includes a node, and
wherein the controller is further configured to input the data set to the first trained machine learning model, acquire a node value of the node when the data set is input, and determine whether the data set is included in the first area or the second area based on the node value.

5. The memory system according to claim 1,
wherein the first trained machine learning model includes a node,
wherein the memory system further comprises a memory,
wherein the controller is further configured to:
store, in the memory, node value information with a minimum value and a maximum value of node values of the node when each of a plurality of pieces of training data is input to the first trained machine learning model;
select the first acquisition operation when a node value of the node during inputting of the data set to the first trained machine learning model is greater than the minimum value and less than the maximum value; and
select the second acquisition operation when the node value is less than the minimum value or the node value is greater than the maximum value.

6. The memory system according to claim 5,
wherein the plurality of pieces of training data are classified into a plurality of groups,
wherein, the node value information includes a minimum value and a maximum value for each of the plurality of groups, and
wherein, for each of the plurality of groups, the controller is further configured to compare a node value of the node during inputting of the data set to the first model with the minimum value and the maximum value.

7. The memory system according to claim 5, wherein the controller is further configured to select the first acquisition operation when a node value of the node during inputting of the data set to the first trained machine learning model is equal to the minimum value or the maximum value.

8. The memory system according to claim 5, wherein the controller is further configured to select the second acquisition operation when a node value of the node during inputting of the data set to the first trained machine learning model is equal to the minimum value or the maximum value.

9. The memory system according to claim 5, wherein the controller is further configured to:
calculate a first value for acquiring the actual read voltage by the first acquisition operation and the second acquisition operation; and
store the first value in the memory.

10. A control method executed by a controller, the method comprising:
acquiring a data set corresponding to a distribution of threshold voltages of a plurality of memory cells by reading the plurality of memory cells using a reference read voltage;
selecting one from a plurality of acquisition operations of acquiring an actual read voltage for reading data stored in the plurality of memory cells based on the data set; and
acquiring the actual read voltage using the selected acquisition operation and reading the plurality of memory cells using the acquired actual read voltage,
wherein the plurality of acquisition operations include a first acquisition operation of acquiring the actual read voltage from the data set using a first trained machine learning model and a second acquisition operation different from the first acquisition operation.

11. The control method according to claim 10, further comprising:
detecting that the data set is included in the first area;
in response to detecting that the data set is included in the first area, selecting the first acquisition operation;
detecting that the data set is included in the second area;
in response to detecting that the data set is included in the second area, selecting the second acquisition operation, and
an appearance frequency of training data of the first trained machine learning model in the first area is higher than an appearance frequency of training data of the first trained machine learning model in the second area.

12. The control method according to claim 10, further comprising:
inputting the data set to a second trained machine learning model; and
determining whether the data set is included in the first area or the second area based on an output value from the second trained machine learning model.

13. The control method according to claim 10, wherein the first trained machine learning model includes a node, and
the method further comprises:
inputting the data set to the first trained machine learning model;
in response to inputting the data set, acquiring a node value of the node; and
determining whether the data set is included in the first area or the second area based on the node value.

14. The control method according to claim 9, wherein the first trained machine learning model includes a node, and
the method further comprising:
inputting each of a plurality of pieces of training data to the first trained machine learning model;
in response to inputting each of the plurality of pieces of training data to the first trained machine learning model, storing node value information with a minimum value and a maximum value of node values of the node;
detecting that a node value of the node during inputting of the data set to the first trained machine learning model is greater than the minimum value and less than the maximum value;
in response to detecting that the node value of the node during inputting of the data set to the first trained machine learning model is greater than the minimum value and less than the maximum value, selecting the first acquisition operation;
detecting that the node value is less than the minimum value or the node value is greater than the maximum value; and
in response to detecting that the node value is less than the minimum value or the node value is greater than the maximum value, selecting the second acquisition operation.

15. The control method according to claim 14, wherein
the plurality of pieces of training data are classified into a plurality of groups,
in the node value information, a minimum value and a maximum value are recorded for each of the plurality of groups, and
the method further comprises, for each of the plurality of groups, comparing a node value of the node during inputting of the data set to the first model with the minimum value and the maximum value.

16. The control method according to claim 14, further comprising:
detecting that a node value of the node during inputting of the data set to the first trained machine learning model is equal to the minimum value or the maximum value; and
in response to detecting that the node value of the node during inputting of the data set to the first trained machine learning model is equal to the minimum value or the maximum value, selecting the first acquisition operation.

17. The control method according to claim 14, further comprising:
detecting that a node value of the node during inputting of the data set to the first trained machine learning model is equal to the minimum value or the maximum value; and
in response to detecting that the node value of the node during inputting of the data set to the first trained machine learning model is equal to the minimum value or the maximum value, selecting the second acquisition operation.

18. The control method according to claim 14, further comprising:
calculating a first value for acquiring the actual read voltage by the first acquisition operation and the second acquisition operation; and
storing the first value in the memory.
